(19) United States
(12) Patent Application Publication
(10) Pub. No.: US 2004/0227068 A1
(43) Pub. Date: Nov. 18, 2004

(54) Methods and apparatus for sensor alignment

(75) Inventors: Jeffrey Raynor, Edinburgh (GB); Jean-Luc Jaffard, Saint Egreve (FR)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: STMicroelectronics Ltd., Marlow - Buckinghamshire (GB)

(21) Appl. No.: 10/677,850

(22) Filed: Oct. 2, 2003

(30) Foreign Application Priority Data
Oct. 2, 2002 (EP) 02256848.9
Aug. 26, 2003 (EP) 03255280.4

(51) Int. Cl. H01L 27/00; H01J 5/02

(52) U.S. Cl. 250/239; 250/208.1

(57) ABSTRACT

A method for attaching a sensor and a housing to opposite sides of a mounting substrate is provided. The sensor has a sensing face that includes a sensing area and at least one signal output contact thereon. The mounting substrate has a circuitry face and at least one signal input contact thereon. The mounting substrate also has an opening therethrough. The method includes positioning the sensing area over the opening so that the at least one signal output contact of the sensor makes contact with the at least one signal input contact of the mounting substrate. The mounting substrate receives the housing so that the housing and the sensor are in alignment.

### FIELD OF THE INVENTION

The present invention relates to sensor alignments, and in particular, to a method of attaching a sensor and a housing to opposite sides of a substrate, a method of attaching a sensor to a substrate, and an aligned sensor package.

### BACKGROUND OF THE INVENTION

In the manufacture of CMOS image sensors and bio-optical sensor systems, the packaging and assembly of the sensor is a very significant portion of the total cost. A key requirement for sensors is accurate alignment of the sensor with respect to a housing that includes a device for transmitting information to the sensor. For example, if the housing includes a lens, it is important that the lens be accurately aligned with the sensor to form an image at the correct place and orientation thereon so that the image produced is not skewed. Similarly, if the housing includes a matter delivery system for a bio-optical sensor system, it is important that the analyte and reagent materials are delivered to the appropriate points so that the amount of light generated accurately reflects the parameter to be detected.

However, accurate alignment has to be achieved without compromising the cost of production or the size of the finished article. Currently, the lowest cost packaging method that is practical is optical thin quad flat packaging (TQFP). However, alignment tolerances using this method are typically several hundred micrometers.

### SUMMARY OF THE INVENTION

In view of the foregoing background, an object of the present invention to provide a method of attaching an optical sensor to a printed circuit board that results in a more accurate alignment between the sensor and housing, while remaining inexpensive to perform in the sensor manufacture process, and one that does not compromise the size of the final aligned sensor package.

According to a first aspect of the present invention, there is provided a method of attaching a sensor and a housing to opposite sides of a stratum as set out in claim 1 of the attached claims.

According to a second aspect of the present invention, there is provided a method of attaching a sensor to a stratum as set out in claim 2 of the attached claims.

According to a third aspect of the present invention, there is provided an aligned sensor package as set out in claim 21 of the attached claims.

### BRIEF DESCRIPTION OF THE DRAWINGS

Embodiments of the present invention will now be described, by way of example only, with reference to the accompanying drawings, in which:

FIG. 1 shows a first embodiment of the present invention, in which a lens is aligned with a sensor; and

FIG. 2 shows a second embodiment of the present invention, in which a matter delivery system is aligned with a sensor.

### DETAILED DESCRIPTION OF THE PREFERRED EMBODIMENTS

Several methods have been developed for attaching chips to printed circuit boards. In one such method, known as flip chip technology, a chip is bump bonded face down onto a substrate. This saves space in that the bump bonds form the electrical connections across which signals can flow between the circuitry on the chip and the printed circuit board.

However, when manufacturing optical devices, where the chip comprises a charge-coupled device or a CMOS sensor with a photodiode array, flip chip technology is not used. The sensing face of the sensor needs to be exposed to light, so it is not possible to have it face down on a board.

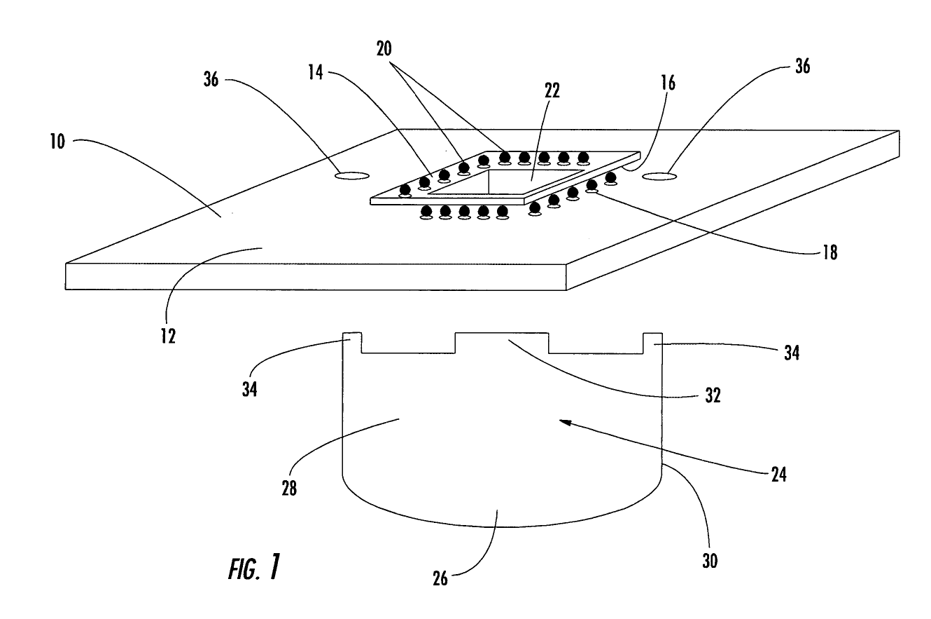

The present invention provides methods and apparatus for the implementation of flip chip technology in the manufacture of optical sensors. FIG. 1 illustrates a first embodiment of the present invention. A printed circuit board (PCB) 10 acts as a substrate for the attachment of a sensor 14 and a housing 24. It has a circuitry face 12 and is provided with an aperture 22. The PCB lands 18 are situated around the aperture 22 and are provided with bump bonds 20. The bump bonds 20 can be formed from an appropriate solder.

A CMOS image sensor 14 has a sensing face 16 that comprises a photodiode array together with circuitry that converts the light received by the photodiode array into electrical signals. These signals can then be transmitted through signal output contacts (not shown). A housing 24 comprises a mating projection 32 that mates with the aperture 22 so that the housing 24 can be aligned with the PCB 10 and a lens 26.

In the preferred embodiment, the lens 26 and body 28 are integrated such that the housing 24 is a unitary article. This is a cost effective production option. However, it is equally possible that the lens 26 may be separable from the body 28. In either case, the lens 26 and the body 28 can optionally be threadably engaged so that the position of the lens 26 is longitudinally adjustable with respect to the body 28 to enable adjustment of the focus of the optical device.

Accordingly, the present invention provides for a method for attaching the sensor 14 and the housing 24 to opposite sides of the PCB 10. The image sensor 14 is attached to the circuitry face 12 of the PCB 10. The sensor 14 is flipped so that the sensing face 16 faces the circuitry face 12 of the PCB 10, and then positioned such that the signal output contacts of the image sensor 14 contact the bump bonds 20, which are positionally commensurate with the PCB lands 18. Thus, the image sensor is placed over the aperture 22.

The bump bonds 20 are then heated to melt the solder and to make electrical connection between the signal output contacts (not shown) of the image sensor 14 and the PCB lands 18. As the bump bonds 20 melt, they try to minimize forces in the surface tension, thus deforming evenly. The net effect of this action draws the image sensor 14 into precise alignment with the aperture.

The housing 24 is attached to the reverse side of the PCB 10. The mating projection 32 is fitted into the aperture 22 so that the housing is precisely aligned with the PCB 10. The accuracy of this alignment can be further augmented by the provision of additional apertures 36 on the PCB 10, which are engaged by corresponding auxiliary mating projections 34 on the housing 24.

Thus, when in use, the optical assembly allows light to pass through the lens 26 and onto the sensing face 16 of the image sensor 14 to be processed into electrical signals to be sent to the PCB 10. The PCB 10 can be any PCB used for any form of device that requires an optical sensor, for example, a mouse for use with a computer or for image capture by a mobile telephone. The sensor can also be conformally coated to prevent moisture penetration.

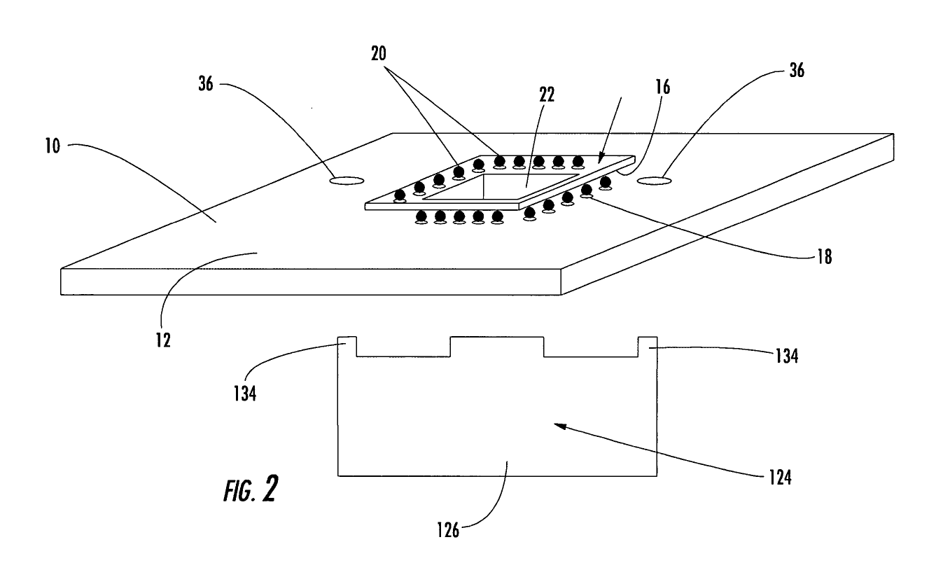

FIG. 2 illustrates a second embodiment of the present invention, which illustrates the application of the principles of the invention to alignment of a bio-optical sensor system. Like reference numerals in FIG. 2 refer to similar components as illustrated in FIG. 1.

In bio-optical sensor systems, a chemical reaction is induced between an analyte and a reagent to produce light. The amount of light produced can be measured and used to monitor the type or amount of particular materials or compounds in the analyte.

A housing 124 comprises a matter delivery system 126 for delivery of analyte and/or reagent. The delivery system could be, for example, a pump, valve or nozzle. The delivery system could be purely for the delivery of an analyte onto the sensor 14, or it could comprise a dual system for the delivery of both analyte and reagent.

The housing 124 comprises a mating projection 132 for connection to the aperture 22 of the PCB 10, and also optionally comprises auxiliary mating projections 134 for connection to mounting holes 36 in the PCB 10.

By ensuring an accurate alignment between the housing and the sensor, less analyte needs to be supplied, thus increasing both the accuracy and efficiency of the system.

The method and apparatus of the present invention provide many advantages over current methods of assembly of optical sensors. In currently used techniques, such as wire bonding or TQFP, a chip has to be attached to a lead frame and the lead frame has to be aligned with a PCB, with wire connectors interconnecting the lead frame and the PCB. These several connections lead to an accumulation of error in alignment, giving tolerances of up to several hundred micrometers, which is undesirable for optical applications where correct alignment is important to ensure produced images are not skewed.

In contrast, the present invention provides for a direct attachment of a chip to a PCB, thus minimizing cumulative errors in alignment of chip to PCB. With this accurate alignment, the projection provided on the housing can simply be placed into the aperture of the PCB so that accurate alignment of the lens to the image sensor is achieved. The accuracy of the alignment of the housing is further ensured with the provision of additional projections that mate with auxiliary apertures on the PCB. This results in the housing and sensor being aligned as follows: to within about one degree of rotational accuracy, to within about twenty micrometers positional accuracy in the plane of the PCB, and to within about ten micrometers positional accuracy in the plane perpendicular to the PCB.

In addition to enabling more accurate alignment, the present invention provides a cheaper alternative to presently used methods of sensor alignment, as a result of its straightforward construction and lack of requirement for molded packaging.

Also, in the manufacture of optical packaging assemblies to accurately align lenses, the sensing face of the image sensor needs to be in the focal plane of an image that is focused through the lens. Thus, the focal length of the lens is a significant factor that increases the size of the final package. In the present invention, because the lens is positioned on the opposite side of the PCB from the sensor rather than being positioned on top of the sensor, the width of the PCB contributes towards the focal length. This means that the size of the overall package can be reduced by a length at least equal to the width of the PCB. This relatively minor space saving may nonetheless make a significant commercial difference.

The size of the package is further minimized by the nature of the flip chip technology. Since wire bonds do not extrude from the perimeter of the chip, the package is compact by nature.

Various modifications and improvements may be incorporated into the above without departing from the scope of the invention. In particular, the bump bonds may be made from any suitable type of solder or other electrically conductive material with suitable thermal properties. The printed circuit board could be any type of surface that can receive electrical signals. The sensor used could be any sensor, not necessarily a charge-coupled device or a CMOS imaging sensor.

Also, the sensing area of the sensing face of a sensor may comprise any suitable image sensor. There are many types of semiconductor based image sensors, all of which can be used within the scope of the invention, for example, charge-coupled devices, or photodiode, phototransistor or photogate sensors.

1-38 (Cancelled).

39. A method of attaching a sensor and a housing to opposite sides of a mounting substrate, the sensor having a sensing face and comprising a sensing area and at least one signal output contact thereon, the mounting substrate having a circuitry face and at least one signal input contact thereon, the mounting substrate also having an opening therethrough, the method comprising:
positioning the sensing area over the opening so that the at least one signal output contact of the sensor contacts the at least one signal input contact of the mounting substrate; and
positioning the housing in contact with the mounting substrate so that the housing and the sensor are in alignment.

40. A method according to claim 39, wherein dimensions of the opening are at least equal to dimensions of the sensing area.

41. A method according to claim 39, wherein dimensions of the opening are at least equal to dimensions of the sensing face.

42. A method according to claim 39, wherein the mounting substrate further comprises circuitry and at least one bump bond thereon, the at least one bump bond being interposed between the at least one signal output contact of the sensor and the at least one signal input contact of the mounting substrate so that signals detected by the sensor are passed to the circuitry.

43. A method according to claim 42, wherein the at least bump bond comprises a plurality of bump bonds around a perimeter of the opening.

44. A method according to claim 42, wherein positioning the sensing area comprises pressing the sensor against the mounting substrate; and further comprising heating the at least one bump bond so that it melts to draw the sensor into alignment over the opening.

45. A method according to claim 39, wherein the sensor comprises at least one of a charge-coupled device and a CMOS image sensor.

46. A method according to claim 39, wherein the sensing area comprises an image sensing area.

47. A method according to claim 46, wherein the image sensing area comprises a photodiode array.

48. A method according to claim 39, wherein the sensor comprises a light sensitive sensor for use with a bio-optical system.

49. A method according to claim 39, wherein the mounting substrate comprises a printed circuit board.

50. A method according to claim 39, wherein the housing comprises a formation extending therefrom; and wherein positioning the housing comprises mating the formation with the opening in the mounting substrate.

51. A method according to claim 39, wherein the housing comprises projections extending therefrom; wherein the mounting substrate includes additional openings therethrough; and wherein positioning the housing comprises mating the projections with the additional openings in the mounting substrate.

52. A method according to claim 39, wherein the housing comprises a lens.

53. A method according to claim 52, wherein the lens is separable from the housing.

54. A method according to claims 52, wherein the lens is threadably attached to the housing.

55. A method according to claim 39, wherein the housing comprises a matter delivery system for delivering a bio-optical analyte to the sensor.

56. A method according to claim 55, where the matter delivery system further delivers a bio-optical reagent to the sensor.

57. A method of attaching a sensor to a mounting substrate, the sensor having a sensing face comprising a sensing area and at least one signal output contact thereon, the mounting substrate having a circuitry face and at least one signal input contact thereon, the mounting substrate also having an opening therethrough, the method comprising:
positioning the sensing area over the opening so that the at least one signal output contact of the sensor contacts the at least one signal input contact of the mounting substrate.

58. A method according to claim 57, wherein dimensions of the opening are at least equal to dimensions of the sensing area.

59. A method according to claim 57, wherein the mounting substrate further comprises circuitry and at least one bump bond thereon, the at least one bump bond being interposed between the at least one signal output contact of the sensor and the at least one signal input contact of the mounting substrate so that signals detected by the sensor are passed to the circuitry.

60. A method according to claim 59, wherein the at least bump bond comprises a plurality of bump bonds around a perimeter of the opening.

61. A method according to claim 59, wherein positioning the sensing area comprises pressing the sensor against the mounting substrate; and further comprising heating the at least one bump bond so that it melts to draw the sensor into alignment over the opening.

62. A method according to claim 57, wherein the sensor comprises at least one of a charge-coupled device and a CMOS image sensor.

63. A method according to claim 57, wherein the sensing area comprises an image sensing area.

64. A method according to claim 57, wherein the sensor comprises a light sensitive sensor for use with a bio-optical system.

65. A method according to claim 57, wherein the mounting substrate comprises a printed circuit board.

66. A sensor package comprising:
a mounting substrate having a circuitry face side and at least one signal input contact thereon, said mounting substrate also having an opening therethrough;
a sensor on the circuitry face side of said mounting substrate and having a sensing face comprising a sensing area and at least one signal output contact thereon, the sensing area being over the opening so that the at least one signal output contact contacts the at least one signal input contact of said mounting substrate; and
a housing on a back side of said mounting substrate opposite the circuitry face side and being aligned with said sensor.

67. A sensor package according to claim 66, wherein dimensions of the opening are at least equal to dimensions of the sensing area.

68. A sensor package according to claim 66, wherein said mounting substrate comprises at least one bump bond; and wherein the at least one signal output contact and the at least one signal input contact are electrically connected via the at least one bump bond.

69. A sensor package according to claim 68, wherein the at least one bump bond comprises a plurality of bump bonds around a perimeter of the opening.

70. A sensor package according to claim 66, wherein said sensor comprises at least one of a charge-coupled device or and a CMOS image sensor.

71. A sensor package according to claim 66, wherein the sensing area comprises an image sensing area.

72. A sensor package according to claim 71, wherein said image sensing area comprises a photodiode array.

73. A sensor package according to claim 66, wherein said sensor comprises a light sensitive sensor for use with a bio-optical system.

74. A sensor package according to claim 66, wherein said mounting substrate comprises a printed circuit board.

75. A sensor package according to claim 66, wherein said mounting substrate includes additional openings therethrough; and wherein said housing comprises projections extending therefrom that are mated with the additional openings.

76. A sensor package according to claim 66, wherein said housing comprises a lens.

77. A sensor package according to claim 76, wherein said lens is separable from said housing.

78. A sensor package according to claim 77, wherein said lens is threadably attached to said housing.

79. A sensor package according to claim 66, wherein said housing comprises a matter delivery system for delivering a bio-optical analyte to said sensor.

80. A sensor package according to claim 79, wherein said matter delivery system also delivers a reagent to said sensor.
